(19) United States
(12) Patent Application Publication
(10) Pub. No.: US 2009/0121249 A1
(43) Pub. Date: May 14, 2009

(54) PACKAGE STRUCTURE OF A LIGHT EMITTING DIODE DEVICE AND METHOD OF FABRICATING THE SAME

(75) Inventors: WEN LIANG TSENG, HSINCHU CITY (TW); LUNG HSIN CHEN, HSINCHU COUNTY (TW)

Correspondence Address: WPAT, PC;INTELLECTUAL PROPERTY ATTORNEYS, 2030 MAIN STREET, SUITE 1300, IRVINE, CA, 92614, US

(73) Assignee: ADVANCED OPTOELECTRONIC TECHNOLOGY INC., HSINCHU COUNTY (TW)

(21) Appl. No.: 12/264,496

(22) Filed: Nov. 4, 2008

(30) Foreign Application Priority Data
Nov. 14, 2007 (TW) 096142956

(51) Int. Cl. H01L 33/00; H01L 21/02

(52) U.S. Cl. 257/98; 438/27; 257/E21.002; 257/E33.072

(57) ABSTRACT

A package structure for light emitting diode devices comprises a substrate having a reflective cavity, a die mounted inside the reflective cavity, a reflective layer disposed on the surface of the reflective cavity, a plurality of electrodes disposed under the surface of the substrate which is opposite to the reflective cavity, and a dual brightness enhancement film overlaid on the reflective cavity. The dual brightness enhancement film efficiently reflects the polarized light that is generated from the die and is not in a transparent direction back to the reflective layer. Subsequently, this light is reflected from the reflective layer to the dual brightness enhancement film. The portions of the reflected light propagating in the same direction as the transparent direction will transmit through the package structure.

### BACKGROUND OF THE INVENTION

1. Field of the Invention

The present invention relates to a package structure for light emitting diode (LED) devices and a method of fabricating the same, and more particularly to an LED device with the ability to increase the intensity of a specific polarized light.

2. Description of the Related Art

LEDs (light emitting diode) have advantages including compact size, high illuminating efficiency and long life. They are anticipated to be the best light source for the future. Because of the rapid development of LCDs (liquid crystal display) and the trend of full-sized screen displays, white light LEDs are applied not only to indication lamps and large size screens but also to consumer electronics products (e.g., cell phones and personal digital assistants).

With breakthroughs in the research of new materials, illuminating efficiency and output power of LEDs are increased continuously and the brightness of LEDs are gradually approaching that of conventional light sources. Due to the high color saturation of LEDs, LEDs have advantages in illumination and as the light source for LCD back light modules. For comparison, under 100 W output energy, an incandescent bulb converts 12% of energy to heat, 83% of energy to infrared radiation, and 5% of energy to visible light; in contrast, the LED converts 15% of energy to visible light and the remaining 85% to heat.

The back light module is a key component of an LCD panel. It provides brightness and uniform light source for an LCD panel displaying images. A back light module is composed of a light source (cold cathode fluorescent lamp, hot cathode fluorescent lamp, light emitting diode etc.), lampshade, reflector, light guide plate, diffuser plate, brightness enhancement film and frame. The types of back light module can be divided into two types: front light type and back light type. The back light types are classified according to the requirements of the specification and the positions of lamps or LEDs. The two different types are as follows:

(1) Side-emitting type structure: a light source is placed on the side of a module and a light guide plate is manufactured by molding injection without printed patterns. This structure is usually used for back light modules smaller than 18 inches in size. The features of this type include lightweight, a thin profile, narrow frame, and low power consumption. At present, some large size back light modules adopt this kind of structure.

(2) Direct type structure: For super-large size back light modules, side-emitting type structures exhibit comparatively poor features of weight, power consumption, and brightness. A direct type structure with light sources at the bottom but without a light guide plate is developed. Light from a lamp or an LED will be reflected by a reflector and evenly diffused by a diffuser. The light then passes through the front surface of the LCD panel. Because of larger space, more lamps can be used in accordance with larger panels. This type has the advantages of better color, wide viewing angle, and a simpler structure. It is suitable for LCD and liquid crystal TV applications. However, the thickness, weight and power consumption are increased. Moreover, high power consumption (when using a cold cathode fluorescent lamp), uneven brightness, and overheating are problems that need to be solved.

Light emitted by the sun or by a lamp is unpolarized light. Such light waves are created by electric charges that vibrate in a variety of directions, thus creating an electromagnetic wave that vibrates in a variety of directions. A polarizer modulates an unpolarized light beam into a light beam that vibrates in a specific direction. That is, the polarizer can limit the light beam through it to only those rays with a selected direction by filtering others out. Therefore, with an LCD panel without a polarizer, unpolarized light can pass into and out of the LCD panel freely. If an LCD panel has polarizers on both the front and rear sides of an LC layer, rotating the LC molecules can control the quantity of the light passing through of the LCD panel.

The LED device has been used as a light source for back light modules. However, there is no dual brightness enhancement film in the package structure of the device. Some portions of light produced by the LED will not pass through the polarizer.

From the above, a package structure of LED that can enhance the light with specific polarized direction and increase the usage ratio of the light produced by a back light module is needed for the market.

### SUMMARY OF THE INVENTION

An aspect of the present invention is to provide a package structure for light emitting diode devices and a method of fabricating the same. A dual brightness enhancement film is used for the light emitting diode devices to enhance the intensity of a light with a specific polarization orientation. With enhanced intensity, the usage ratio of the light in the back light module of an LCD and the image quality produced by the LCD can be increased.

The present invention discloses a package structure for light emitting diode devices, comprising a substrate having a reflective cavity, a die mounted inside the reflective cavity, a reflective layer disposed on the surface of the reflective cavity, a plurality of electrodes disposed under the surface of the substrate which is opposite to the reflective cavity, and a dual brightness enhancement film overlaid on the reflective cavity. The dual brightness enhancement film efficiently reflects the light that is generated from the die and is not in a transparent direction back to the reflective layer. Subsequently, this light will be reflected from the reflective layer to the dual brightness enhancement film. The portions of the reflected light propagating in the same direction as the transparent direction will transmit through the package structure.

A plurality of solder pads is electrically connected to the contacts of the die. The contacts of the die are connected to the solder pad by metal wires or solder bump.

The package structure for a light emitting diode device further comprises a plurality of conductive pillars penetrating the substrate and electrically connected to the solder pads.

The material of the substrate includes a silicon material, a ceramic material, a polymeric material, a glass, or a low temperature co-fired ceramic material.

The dual brightness enhancement film efficiently reflects the die-produced polarized light that is not in a transparent direction back to the reflective layer.

The package structure for a light emitting diode device further comprises a transparent insulating material filled in the reflective cavity and the dual brightness enhancement film overlaid on the transparent insulating material.

The present invention also discloses a method for fabricating the package structure of a light emitting diode device, comprising the steps of: providing a substrate; forming a reflective cavity on a first surface of the substrate; forming a reflective layer on the surface of the reflective cavity; forming a plurality of electrodes under a second surface of the substrate, wherein the second surface is opposite to the first surface; mounting a die inside the reflective cavity; and overlaying a dual brightness enhancement film on the reflective cavity, whereby the dual brightness enhancement film reflects the die-produced polarized light that is not in a transparent direction back to the reflective cavity.

The fabricating method further comprises a step of disposing a plurality of solder pads inside the reflective cavity.

The fabricating method further comprises steps of forming a plurality of through holes and disposing a metal conductive pillar in each of the through holes, wherein the solder pads are electrically connected to the electrodes by the metal conductive pillars.

The fabricating method further comprises a step of filling transparent insulating material in the reflective cavity.

The die is mounted in the reflective cavity by using a die bonding method or a flip chip bonding method.

### BRIEF DESCRIPTION OF THE DRAWINGS

The invention will be described according to the appended drawings in which:

FIG. 1 is a cross-sectional diagram showing a light emitting diode device in accordance with the present invention;

FIG. 2 is a cross-sectional diagram showing a light emitting diode device in accordance with another embodiment of the present invention;

FIGS. 3A-3D are diagrams respectively showing reflective polarizers that increase the intensity of a specific polarized light; and

FIGS. 4A-4H are diagrams respectively corresponding to each step of fabrication in accordance with the present invention.

### PREFERRED EMBODIMENT OF THE PRESENT INVENTION

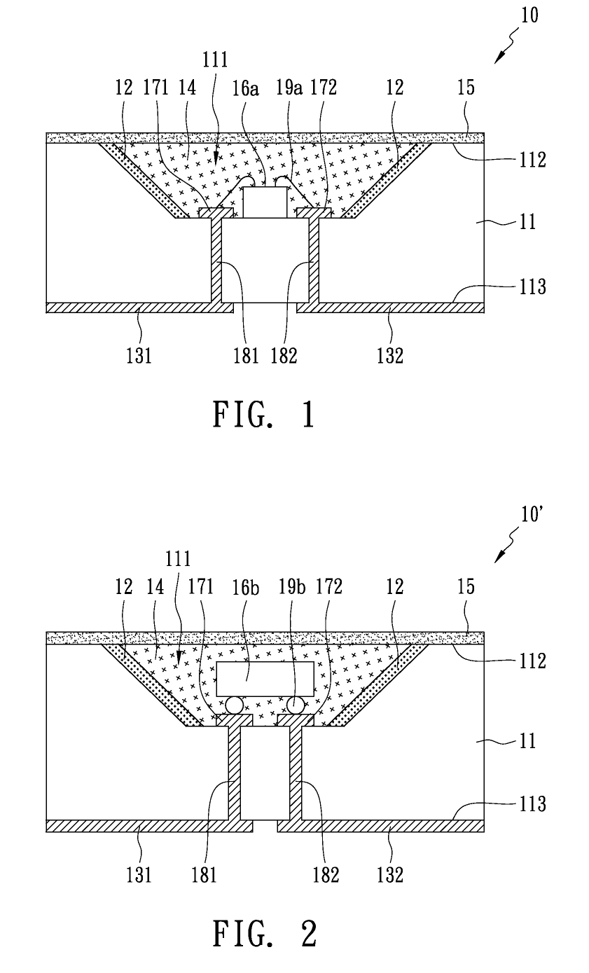

FIG. 1 is a cross-sectional diagram showing a light emitting diode device in accordance with the present invention. A light emitting diode device 10 comprises a substrate 11 having a reflective cavity 111, a die 16a mounted inside the reflective cavity 111, a reflective layer 12 disposed on the surface of the reflective cavity 111, a plurality of electrodes 131-132 disposed under the surface of the substrate 11 which is opposite to the reflective cavity 111, and a dual brightness enhancement film 15 overlaid on the reflective cavity 111. A concave reflective cavity 111 is formed on the first surface 112 of the substrate 11 and the electrodes 131-132 are disposed under the second surface 113 of the substrate 11. The material of the substrate 11 can be a silicon material, a ceramic material, a polymeric material, a glass, or a low temperature co-fired ceramic material. A plurality of solder pads 171-172 are disposed on the bottom of the reflective cavity with a cup shape and the solder pads 171-172 are electrically connected to the electrodes 131-132 by conductive pillars 181-182.

The die is mounted on the bottom of the reflective cavity 111 with a cup shape by using a die bonding method. A wire bonding procedure is used to connect the contacts of the die 16a and the solder pads 171-172 by conductive metal wires 19a that are 18-50 um in diameter. The electric signal can thus be transmitted between the die 16a and the substrate 11 by the conductive metal wires 19a. In order to protect the die 16a and the conductive metal wires 19a from the damage of an external force or environmental factors, a transparent insulating material 14 needs to be used to overlay the conductive metal wires 19a, the reflective cavity 111 with a cup shape, and the die 16a. The transparent insulating material 14 is filled into the reflective cavity 111. Moreover, the dual brightness enhancement film 15 is overlaid on the transparent insulating material 14. This dual brightness enhancement film 15 reflects polarized light that is not in a transparent direction back to the reflective layer 12 efficiently, wherein the transparent direction is the direction permitted by the dual brightness enhancement film 15 for a specific polarized light to propagate.

The polarized light reflected by the dual brightness enhancement film 15 back to the reflective layer is again reflected from the reflective layer 12 to the dual brightness enhancement film 15. The portions of the reflected light propagating in the same direction as transparent direction will pass through the dual brightness enhancement film 15.

FIG. 2 is a cross-sectional diagram showing a light emitting diode device 10′ in accordance with another embodiment of the present invention. The contacts of a die 16b are electrically connected to the solder pads 171-172 by a bump 19b. Due to the shorter signal-transmitting path created by a flip chip packing type, the signal quality is improved considerably over that of a longer signal-transmitting path which causes a time delay and weakened signals.

Generally speaking, a polarizer can modulate an unpolarized light beam into a light beam that vibrates in a specific direction. That is, the polarizer limits the light beam through it to only those rays with a selected direction by filtering others out. Therefore, with an LCD panel without a polarizer, unpolarized light can pass into and out of the LCD panel. If an LCD panel has polarizers on both front and rear sides of an LC layer, rotating the LC molecules can control the quantity of the light passing through of the LCD panel. The structure of a polarizer is composed of several thin film layers. The layer is frequently made of dyeing a polyvinyl alcohol (PVA) film with dichromatic iodine or dichromatic dye. After warming up the PVA film, this film is lengthened to several times of the original length. Consequently, the PVA film becomes thinner and narrower. Originally, the orientations of the molecules in the PVA film are random. After lengthening, the orientations of the molecules in the PVA are changed to the direction of the force and then the dichromatic iodine or dichromatic dye inside the PVA film is aligned toward that direction. Therefore, the PVA film will absorb the electric fields parallel to the direction of molecules and will let the electric fields perpendicular to the direction of molecules pass. After lengthening, the PVA film becomes fragile. The triacetyl cellulose (TAC) layers are adhered on the both sides of PVA film for protection.

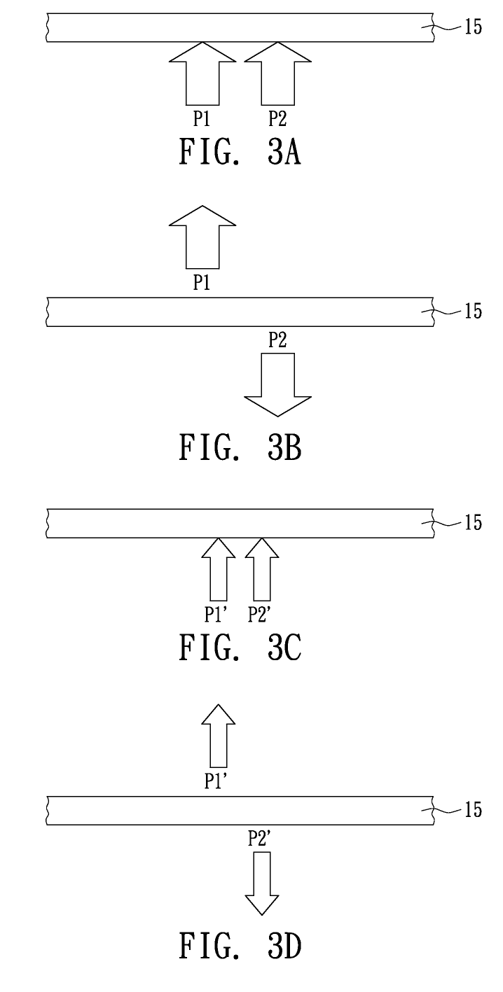

As shown in FIGS. 3A-3D, the dual brightness enhancement film 15 is made by a stacked film technique and reflects the polarized light P2 that is not in a transparent direction back efficiently. On the other hand, the polarized light P1 that is in a transparent direction will pass through the dual brightness enhancement film 15. According to the effects of the diffusion and the scrambling of the reflective layer 12, some of the polarized light P2 becomes polarized light P1′ that is in a transparent direction, while the remainder of the polarized light P2 becomes polarized light P2′ that is still not in a transparent direction. By repetition of the above action, most polarized light that is not in a transparent direction will finally pass through the dual brightness enhancement film 15.

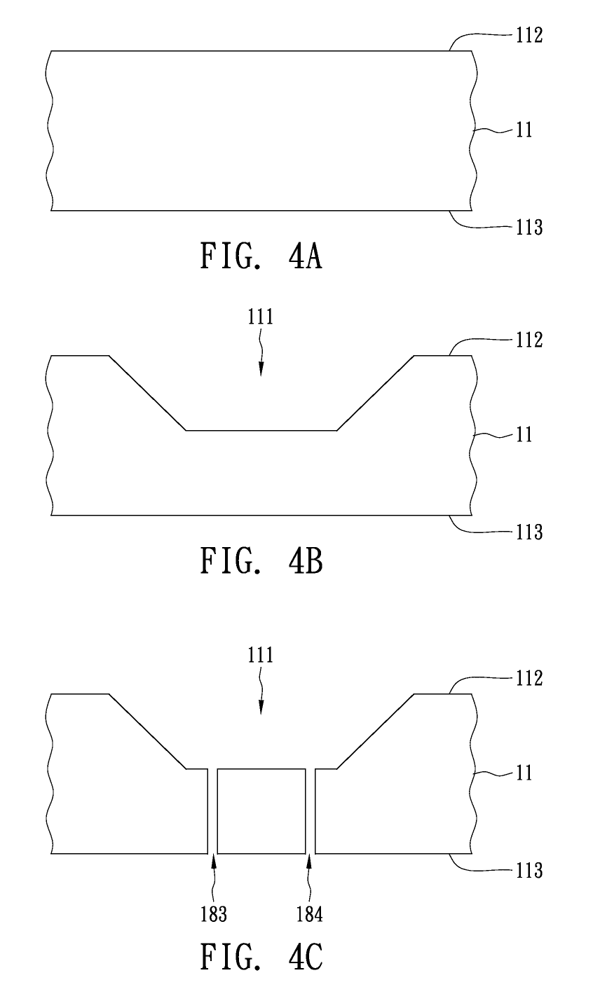

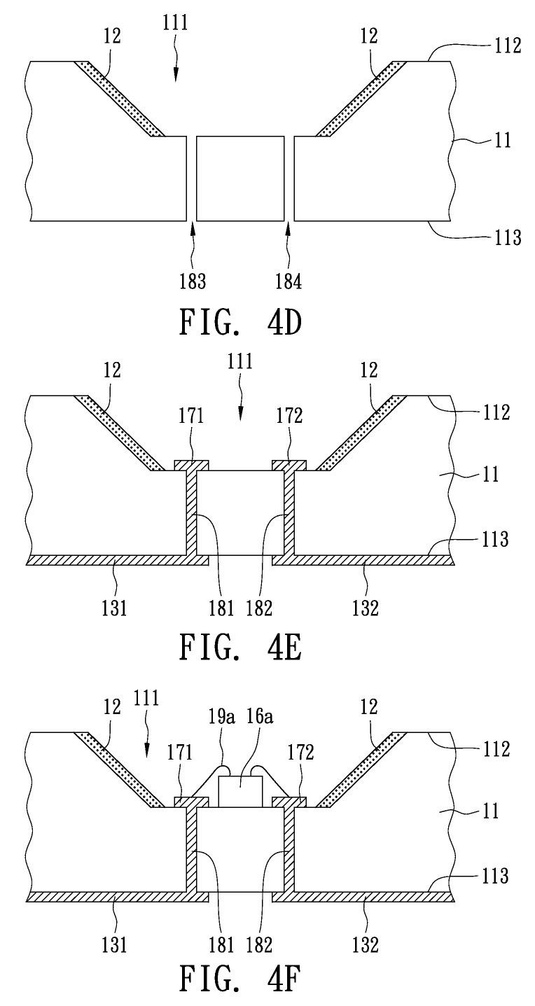

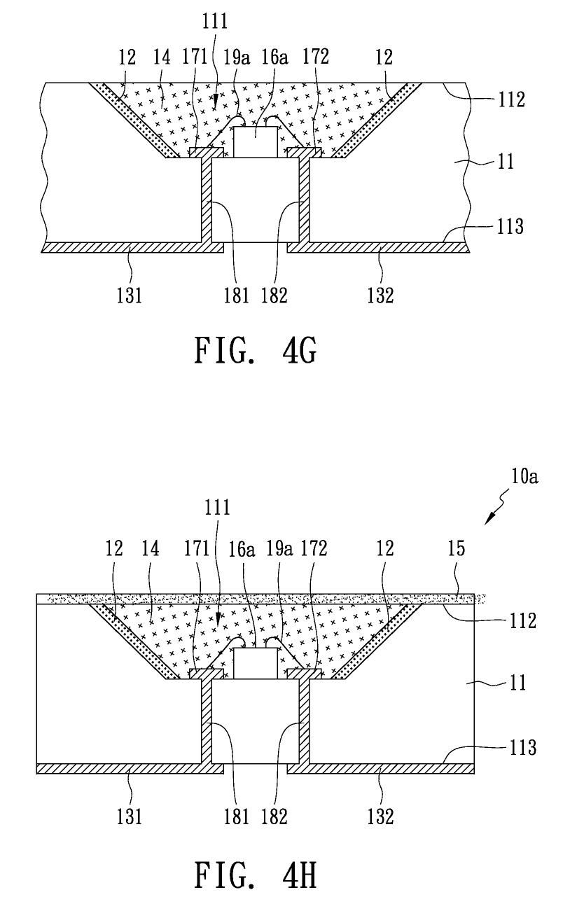

FIGS. 4A-4H are diagrams corresponding to each step of fabrication in accordance with the present invention. First, a substrate 11 is provided, and then a reflective cavity 111 is formed on the first surface 112 of the substrate 11. Moreover, a plurality of through holes 183-184 between the reflective cavity 111 and the second surface 113 of the substrate 11 are formed on the substrate 11. A reflective layer 12 is formed on both sides of the reflective cavity 111 and a plurality of solder pads 171-172 are disposed on the bottom of the reflective cavity 111. A plurality of electrodes 131-132 is formed under the second surface 113 of the substrate 11. Filling the metal material into the through holes 183-184 forms conductive pillars 181-182. In addition, a die 16a is mounted on the bottom of the reflective cavity 111. The contacts of the die 16a are connected to the solder pads 171-172 by metal wires 19a. A transparent insulating material 14 is then filled into the reflective cavity 111. Finally, the dual brightness enhancement film 15 is overlaid on the transparent insulating material 14. This dual brightness enhancement film 15 reflects the die-produced polarized light that is not in a transparent direction back to the reflective layer 12 efficiently.

The above-described embodiments of the present invention are intended to be illustrative only. Numerous alternative embodiments may be devised by persons skilled in the art without departing from the scope of the following claims.

What is claimed is:

1. A package structure for light emitting diode devices, comprising:
a substrate having a reflective cavity;
a die mounted inside the reflective cavity;
a reflective layer disposed on the reflective cavity;
a plurality of electrodes disposed under a surface of the substrate opposite to the reflective cavity; and
a dual brightness enhancement film overlaid on the reflective cavity.

2. The package structure of claim 1, wherein the reflective cavity has a plurality of solder pads electrically connected to contacts of the die.

3. The package structure of claim 2, wherein the contacts of the die are connected to the solder pads by using metal wires.

4. The package structure of claim 2, wherein the contacts of the die are connected to the solder pads through solder bump.

5. The package structure of claim 2, further comprising a plurality of conductive pillars penetrating the substrate and electrically connected to the solder pads.

6. The package structure of claim 1, wherein the material of the substrate is a silicon material, a ceramic material, a polymeric material, a glass, or a low temperature co-fired ceramic material.

7. The package structure of claim 1, wherein the dual brightness enhancement film efficiently reflects polarized light that is generated form the die and is not in a transparent direction back to the reflective layer.

8. The package structure of claim 1, further comprising a transparent insulating material filled in the reflective cavity and the dual brightness enhancement film overlaid on the transparent insulating material.

9. A fabrication method of a package structure for light emitting diode devices, comprising the steps of:
providing a substrate;
forming a reflective cavity on a first surface of the substrate;
forming a reflective layer on the reflective cavity;
forming a plurality of electrodes under a second surface of the substrate, wherein the second surface is opposite to the first surface;
mounting a die inside the reflective cavity; and
overlaying a dual brightness enhancement film on the reflective cavity, whereby the dual brightness enhancement film reflects polarized light that is generated form the die and is not in a transparent direction back to the reflective cavity.

10. The method of claim 9, further comprising a step of disposing a plurality of the solder pads inside the reflective cavity.

11. The method of claim 10, further comprising steps of forming a plurality of through holes and disposing a metal conductive pillar in each of the through holes, wherein the solder pads are electrically connected to the electrodes by the metal conductive pillar.

12. The method of claim 9, further comprising a step of filling a transparent insulating material in the reflective cavity.

13. The method of claim 9, wherein the die is mounted in the reflective cavity by using a die bonding method.

14. The method of claim 9, wherein the die is mounted in the reflective cavity by using a flip chip bonding method.
